(19) United States
(12) Patent Application Publication
(10) Pub. No.: US 2014/0209950 A1
(43) Pub. Date: Jul. 31, 2014

(54) LIGHT EMITTING DIODE PACKAGE MODULE

(71) Applicant: LUXO-LED CO., LIMITED, Hong Kong (HK)

(72) Inventor: Shih-Yang TSO, Taipei City (TW)

(73) Assignee: LUXO-LED CO., LIMITED, Hong Kong (HK)

(21) Appl. No.: 14/168,246

(22) Filed: Jan. 30, 2014

Related U.S. Application Data
(60) Provisional application No. 61/758,939, filed on Jan. 31, 2013.

(51) Int. Cl. H01L 33/50; H01L 33/56; H01L 33/58

(52) U.S. Cl. CPC H01L 33/50; H01L 33/58; H01L 33/56
USPC 257/98

(57) ABSTRACT

A light emitting diode module includes a substrate, a light emitting diode die, a transparent layer, a phosphor material layer and a lens layer. The light emitting diode die is disposed on the substrate. The transparent layer disposed on the light emitting diode die. The phosphor material layer disposed on the transparent layer. The lens layer disposed on the phosphor material layer.

### CROSS REFERENCE TO RELATED APPLICATION

The application claims priority based on U.S. provisional application Ser. No. 61/758,939, filed Jan. 31, 2013, entitled LIGHT EMITTING DIODE PACKAGE MODULE, which is hereby incorporated by reference in its entirely.

### BACKGROUND

1. Technical Field

The disclosure relates to a light emitting diode package module.

2. Related Art

A light-emitting diode (LED) is a semiconductor light source. LEDs are used as indicator lamps in many devices and are increasingly used for other lighting. Light-emitting diodes are used in applications as diverse as aviation lighting, automotive lighting, advertising, general lighting, and traffic signals. LEDs have allowed new text, video displays, and sensors to be developed, while their high switching rates are also useful in advanced communications technology. Infrared LEDs are also used in the remote control units of many commercial products including televisions, DVD players, and other domestic appliances.

The phosphor material is now widely used in LED module. For the time being, the phosphor LED package is popular. However, the phosphor material is directly coated on the LED dies. Thus the heat generated from the LED dies may affect the efficiency of the module.

### SUMMARY

The embodiment of the disclosure discloses a light emitting diode module comprising a substrate, a light emitting diode die, a transparent layer, a phosphor material layer and a lens layer. The light emitting diode die is disposed on the substrate. The transparent layer disposed on the light emitting diode die. The phosphor material layer disposed on the transparent layer. The lens layer disposed on the phosphor material layer.

The detailed characteristics and advantages of the disclosure are described in the following embodiments in details, the techniques of the disclosure can be easily understood and embodied by a person of average skill in the art, and the related objects and advantages of the disclosure can be easily understood by a person of average skill in the art by referring to the contents, the claims and the accompanying drawings disclosed in the specifications.

### BRIEF DESCRIPTION OF THE DRAWINGS

The present disclosure will become more fully understood from the detailed description given herein below for illustration only, and thus are not limitative of the present disclosure, and wherein:

FIG. 1 illustrates the light emitting module according to one embodiment of the disclosure; and

FIG. 2 illustrates the light emitting module according to another embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

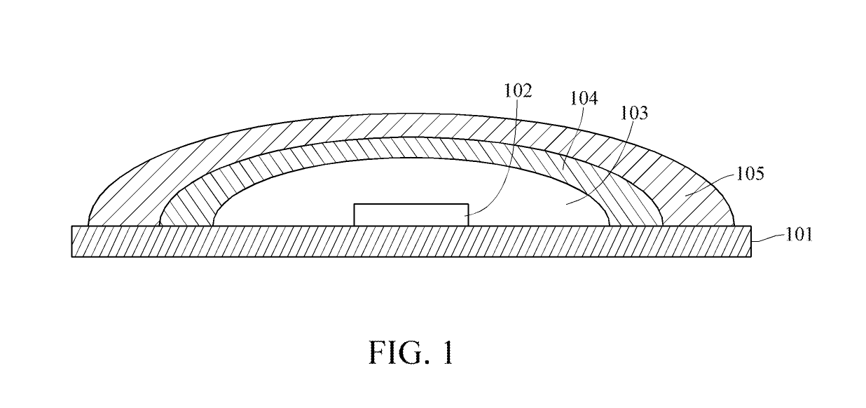

FIG. 1 illustrates the light emitting module according to one embodiment of the disclosure.

The light emitting module includes a substrate 101, a light emitting diode die 102, a transparent layer 103, a phosphor material layer 104 and a lens layer 105. The light emitting diode die 102 is disposed on the substrate 101. The transparent layer 103 disposed on the light emitting diode die 102. The phosphor material layer 104 disposed on the transparent layer 103. The lens layer 105 disposed on the phosphor material layer 104.

The transparent layer 103 prevents direct contact of the phosphor material layer 104 with the light emitting diode die 102. The lens layer 105 is adopted to direct the light emitted from the light emitting diode die 102 to a predetermined direction.

The phosphor material layer 104 converts at least a portion of the light emitted from the light emitting diode die to a light of a different wavelength.

In one embodiment, the material of the substrate 101 is one selected from sapphire (Al₂O₃), silicon carbide (SiC), silicon, and gallium nitride materials.

In one embodiment, the transparent layer 103 is formed of epoxy or silicone.

In one embodiment, the material of the lens layer 105 is a transparent material.

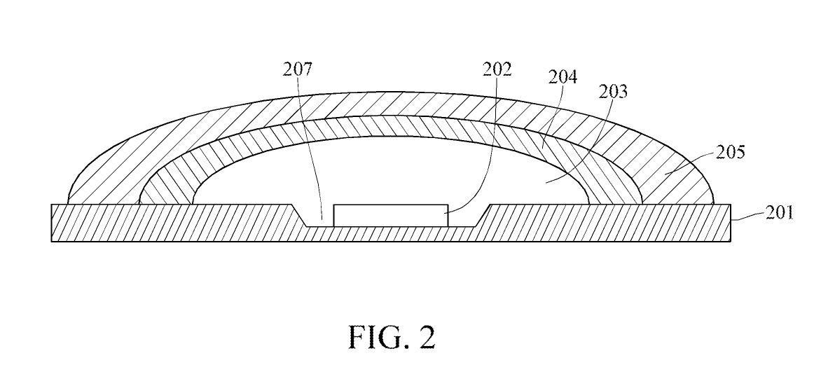

FIG. 2 illustrates the light emitting module according to another embodiment of the disclosure.

The light emitting module includes a substrate 201, a light emitting diode die 202, a transparent layer 203, a phosphor material layer 204 and a lens layer 205. The substrate 201 is formed to have a concave portion 207. The concave portion 207 is used to accommodate the light emitting diode die 202 to enhance the refection capabilities. The transparent layer 203 disposed on the light emitting diode die 202. The phosphor material layer 204 disposed on the transparent layer 203. The lens layer 205 disposed on the phosphor material layer 204.

The transparent layer 203 prevents direct contact of the phosphor material layer 204 with the light emitting diode die 202. The lens layer 205 is adopted to direct the light emitted from the light emitting diode die 202 to a predetermined direction.

The phosphor material layer 204 converts at least a portion of the light emitted from the light emitting diode die to a light of a different wavelength.

In one embodiment, the material of the substrate 202 is one selected from sapphire (Al₂O₃), silicon carbide (SiCs), silicon, and gallium nitride materials.

In one embodiment, the transparent layer 203 is formed of epoxy or silicone.

In one embodiment, the material of the lens layer 205 is a transparent material

The embodiment of the disclosure may have diffuse or anti glare properties. The embodiment of the disclosure further integrates specific additives which result into specific performances. The embodiment of the disclosure further avoids secondary optics and light decay. Through the concave portion of the substrate, the embodiment of the disclosure may have high internal reflection.

Note that the specifications relating to the above embodiments should be construed as exemplary rather than as limitative of the present invention, with many variations and modifications being readily attainable by a person skilled in the art without departing from the spirit or scope thereof as defined by the appended claims and their legal equivalents.

What is claimed is:

1. A light emitting diode package module, comprising:
a substrate;
a light emitting diode die disposed on the substrate;
a transparent layer disposed on the light emitting diode die;
a phosphor material layer disposed on the transparent layer; and
a lens layer disposed on the phosphor material layer.

2. The module according to claim 1, wherein the substrate is formed to have a concave portion to accommodate the light emitting diode.

3. The module according to claim 1, wherein the transparent layer is formed of epoxy or silicone.

4. The module according to claim 1, wherein a material of the lens layer is a transparent material.
